(19) United States
(12) Patent Application Publication
(10) Pub. No.: US 2026/0101452 A1
(43) Pub. Date: Apr. 9, 2026

(54) FLEXIBLE DISPLAY DEVICE METAL SUPPORT, AND FLEXIBLE DISPLAY DEVICE

(71) Applicant: Dai Nippon Printing Co., Ltd., Tokyo-to (JP)

(72) Inventors: Hidetoshi IIOKA, Tokyo-to (JP); Shinichiro TAKAHASHI, Tokyo-to (JP); Masanobu NAKANO, Tokyo-to (JP)

(73) Assignee: Dai Nippon Printing Co., Ltd., Tokyo-to (JP)

(21) Appl. No.: 18/905,270

(22) Filed: Oct. 3, 2024

(51) Int. Cl. H05K 5/02

(52) U.S. Cl. CPC H05K 5/0217

(57) ABSTRACT

A flexible display device metal support includes a first surface, a second surface opposite to the first surface, a first hole formed in the second surface, and a second hole formed in the first surface or the second surface. Each of the first surface and the second surface is parallel to a plane formed by an axis of a first direction and an axis of a second direction. The second hole is located adjacent to the first hole in the first direction. A length of the second hole in the first direction is less than a length of the first hole in the first direction, or a length of the second hole in the second direction is less than a length of the first hole in the second direction.

### CROSS-REFERENCE TO RELATED APPLICATIONS

The present invention contains subject matter related to Japanese Patent Application No. 2023-058922 filed in the Japan Patent Office on Mar. 31, 2023, the entire contents of which are incorporated herein by reference.

### BACKGROUND OF THE INVENTION

### 1. Field of the Invention

The present disclosure relates to a flexible display device metal support and a flexible display device.

### 2. Description of the Related Art

These days, for example, in the field of display devices of smartphones, tablets, and the like, those having a collapsible structure are known. A flexible display device having a bendable portion at its part exists as such a kind of display device, for example, as disclosed in Japanese Patent No. 6,603,764.

These days, it is demanded to reduce the shape size of the bent portion when a flexible display device is folded. That is, it is demanded to reduce the radius of curvature of the bent portion. However, the smaller the shape size of the bent portion is, the more difficult it is to maintain the strength of the bent portion.

For the purpose of improving bending resistance, it is conceivable to form a pattern such as recesses at the bent portion. However, there is a risk that doing so might cause stress concentration at the boundary between the bent portion and the non-bent portion, making this portion susceptible to a breakage. Moreover, since the strength of the metal support changes across the boundary between the bent portion and the non-bent portion, there is a risk that the boundary portion might look like a crease when viewed from the display-surface side.

### SUMMARY OF THE INVENTION

The present disclosure provides a flexible display device metal support and a flexible display device that can suppress stress concentration at a boundary between a bent portion and a non-bent portion and can suppress the deformation of the boundary between the bent portion and the non-bent portion.

Embodiments of the present disclosure relate to [1] to [10] stated below.
[1] A flexible display device metal support, comprising: a first surface; a second surface opposite to the first surface; a first hole formed in the second surface; and a second hole formed in the first surface or the second surface, wherein each of the first surface and the second surface is parallel to a plane formed by an axis of a first direction and an axis of a second direction, the second hole is located adjacent to the first hole in the first direction, and a length of the second hole in the first direction is less than a length of the first hole in the first direction, or a length of the second hole in the second direction is less than a length of the first hole in the second direction.
[2] The flexible display device metal support according to [1], wherein a plurality of second holes, each as the second hole, is formed in the first direction, and, the farther from the first hole, the shorter in length in the first direction or in length in the second direction the plurality of second holes is.
[3] A flexible display device metal support, comprising: a first surface; a second surface opposite to the first surface; a first hole formed in the second surface; and a second hole formed in the first surface or the second surface, wherein each of the first surface and the second surface is parallel to a plane formed by an axis of a first direction and an axis of a second direction, the second hole is located adjacent to the first hole in the first direction, and a depth of the second hole is less than a depth of the first hole.
[4] The flexible display device metal support according to [3], wherein a plurality of second holes, each as the second hole, is formed in the first direction, and, the farther from the first hole, the shallower in depth the plurality of second holes is.
[5] A flexible display device metal support, comprising: a first surface; a second surface opposite to the first surface; a first hole formed in the second surface; and a second hole formed in the first surface or the second surface, wherein each of the first surface and the second surface is parallel to a plane formed by an axis of a first direction and an axis of a second direction, the second hole is located adjacent to the first hole in the first direction, the first hole is formed in a first region, the first region being, in a plan view, a minimum rectangle extending throughout an entirety in the second direction and including all of first holes each as the first hole, the second hole is formed in a second region, the second region being, in a plan view, a minimum rectangle extending throughout the entirety in the second direction and including all of second holes each as the second hole, and a percentage of a volume of the first holes to a volume of an entirety in a thickness direction of the flexible display device metal support at the first region is greater than a percentage of a volume of the second holes to a volume of the entirety in the thickness direction of the flexible display device metal support at the second region.
[6] The flexible display device metal support according to [5], wherein the second hole includes a plurality of first linear grooves extending linearly and a plurality of second linear grooves extending linearly, and each of the first linear grooves and each of the second linear grooves intersect with each other in a non-parallel manner.
[7] The flexible display device metal support according to any one of [1] to [6], wherein the first hole is a non-through hole.
[8] The flexible display device metal support according to any one of [1] to [6], wherein the first hole is a through hole.
[9] The flexible display device metal support according to any one of [1] to [5], [7], and [8], wherein a plurality of second holes, each as the second hole, is formed, and the plurality of second holes is arranged in a staggered manner.
[10] A flexible display device, comprising: a display member; and the flexible display device metal support according to any one of [1] to [9] supporting the display member.

The present disclosure makes it possible to suppress stress concentration at a boundary between a bent portion and a non-bent portion and to suppress the deformation of the boundary between the bent portion and the non-bent portion.

### BRIEF DESCRIPTION OF DRAWINGS

FIG. 1 is a perspective view illustrating a flexible display device according to an embodiment.

FIG. 2 is a plan view illustrating a flexible display device according to an embodiment.

FIG. 3 is a cross-sectional view illustrating a flexible display device according to an embodiment (in an expanded state) (cross-sectional view taken along a line III-III of FIG. 2).

FIG. 4 is a cross-sectional view illustrating a flexible display device according to an embodiment (in a folded state).

FIG. 5 is a plan view illustrating a flexible display device metal support according to an embodiment.

FIG. 6 is a partial cross-sectional view illustrating a flexible display device metal support according to an embodiment (cross-sectional view taken along a line VI-VI of FIG. 5).

FIGS. 7A to 7D are cross-sectional views illustrating a method of manufacturing a flexible display device metal support according to an embodiment.

FIG. 8 is a cross-sectional view illustrating a state in which the flexible display device metal support is bent.

FIG. 9 is a plan view illustrating a flexible display device metal support according to a first variation example.

FIG. 10 is a plan view illustrating a flexible display device metal support according to a second variation example.

FIG. 11 is a cross-sectional view illustrating a flexible display device metal support according to a third variation example.

FIG. 12 is a plan view illustrating a flexible display device metal support according to a fourth variation example.

FIG. 13 is a plan view illustrating a flexible display device metal support according to a fifth variation example.

FIG. 14 is a plan view illustrating a flexible display device metal support according to a sixth variation example.

### DETAILED DESCRIPTION OF THE INVENTION

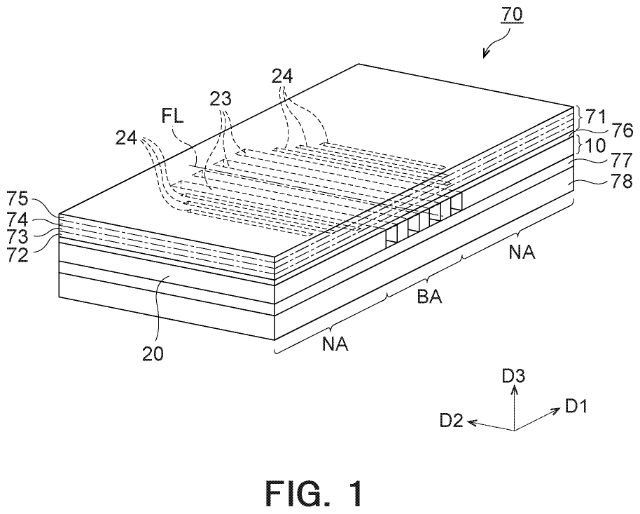

With reference to FIGS. 1 to 8, an embodiment of the present disclosure will now be described. In each of the drawings to which reference is made below, the same reference signs are assigned to the same portions, and a detailed explanation thereof may sometimes be partially omitted.

In this specification, the term “first direction D1” means a direction that lies on a plane parallel to a principal surface of a flexible display device metal support 10 or a flexible display device 70 and is perpendicular to a folding center line FL. The term “second direction D2” means a direction that lies on a plane parallel to a principal surface of the flexible display device metal support 10 or the flexible display device 70 and is parallel to the folding center line FL. The first direction D1 and the second direction D2 may be directions that are parallel to the sides of the flexible display device metal support 10 or the flexible display device 70 respectively. The first direction D1 and the second direction D2 are orthogonal to each other. A third direction D3 is a direction that is perpendicular to both the first direction D1 and the second direction D2 and is parallel to the thickness direction of the flexible display device metal support 10 or the flexible display device 70.

Configuration of Flexible Display Device With reference to FIGS. 1 to 4, an overview of a flexible display device according to the present embodiment is presented below. FIGS. 1 to 4 are diagrams illustrating a flexible display device according to the present embodiment.

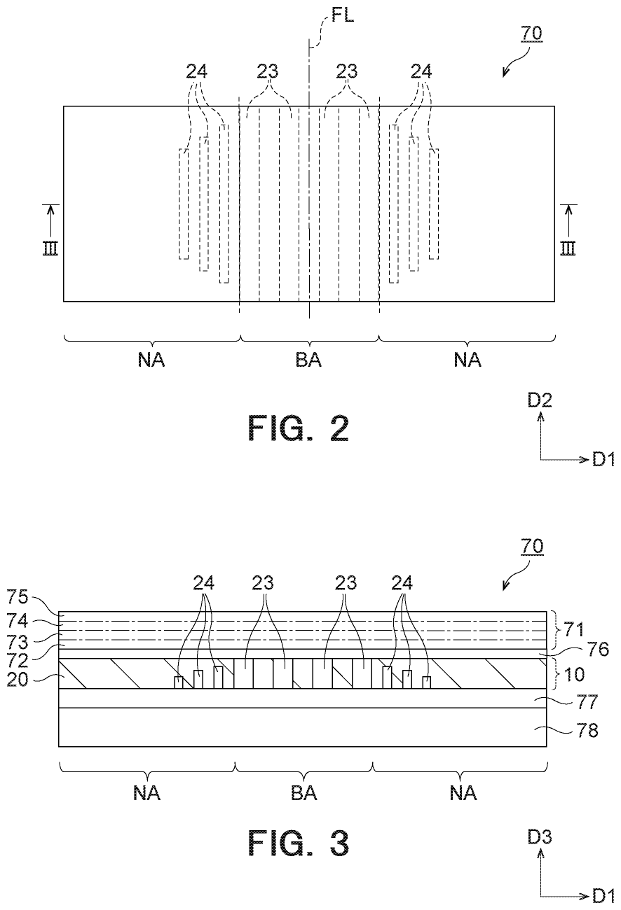

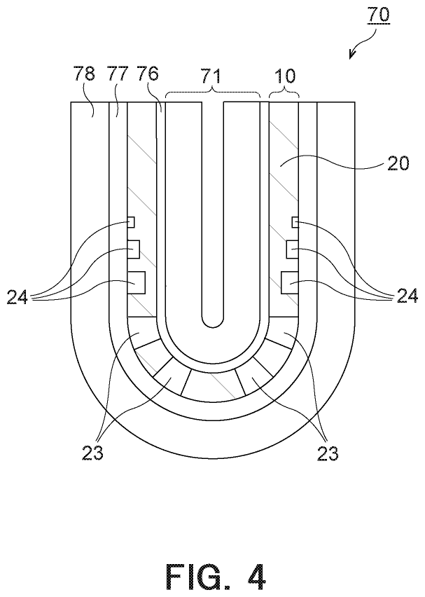

The flexible display device 70 illustrated in FIGS. 1 and 2 may be, for example, an organic electroluminescent (EL) display device. The flexible display device 70 is flexible and has a foldable structure. The flexible display device 70 can be put into a folded state (see FIG. 4), which means a state of being collapsed, and an expanded state (see FIGS. 2 and 3), which means a state of being opened. The folded state is a state in which the flexible display device 70 is folded at its center along the folding center line FL. The folding is performed such that a part of an outer surface of a display member 71 and another part of the outer surface thereof are positioned close to each other in the folded state. Note that this does not imply any limitation. The folding may be performed in such a way as to bring a part of an outer surface of a casing 78 and another part of the outer surface thereof close to each other. The expanded state is a state in which the flexible display device 70 is open without being folded. In the expanded state, the entire surface of the display member 71 lies on substantially the same plane. The flexible display device 70 may be thin electronic equipment that has a section configured to display an image. Such electronic equipment may be, for example, portable terminal equipment such as a smartphone or a tablet.

As illustrated in FIG. 3, the flexible display device 70 includes the display member 71 and the flexible display device metal support 10. The flexible display device metal support 10 will be hereinafter simply referred to also as “metal support 10”. The metal support 10 supports the display member 71. A cushioning layer 76 such as a cushion sheet is provided between the display member 71 and the metal support 10. A heat dissipation layer 77 is disposed on, of the metal support 10, the opposite surface facing away from the display member 71. The display member 71, the cushioning layer 76, the metal support 10, and the heat dissipation layer 77 are supported by the casing 78.

The display member 71 includes a supporting base material 72, a thin-film transistor (TFT) 73, an organic EL element 74, and a sealing resin 75. The thin-film transistor 73 is disposed on the supporting base material 72. The organic EL element 74 is disposed on the thin-film transistor 73. The sealing resin 75 is disposed on the organic EL element 74.

The supporting base material 72 supports the entirety of the display member 71, and may be a film that has flexibility. A synthetic resin material such as, for example, polyethylene terephthalate may be used as the supporting base material 72. The thin-film transistor 73 drives the organic EL element 74, and controls a voltage applied to an electrode of the organic EL element 74. The organic EL element 74 displays an image and the like by self-emission of light. The organic EL element 74 is electrically connected to the thin-film transistor 73. The organic EL element 74 may be called “light emitting section”. The organic EL element 74 may include a non-illustrated reflection electrode, a non-illustrated organic light emission layer, and a non-illustrated transparent electrode. The sealing resin 75 seals the organic EL element 74, and protects the organic EL element 74. The display member 71 is not limited to an organic EL display device. For example, the display member 71 may be another type of display device that has a self-emission function. The display member 71 may be a micro LED display device that includes micro LED elements (light-emitting body).

The cushioning layer 76 is a layer that mitigates the stress applied to the display member 71 when the flexible display device 70 is folded. The cushioning layer 76 may be a layer of a resin material that has elasticity, such as a silicone resin, a polyurethane resin, or an epoxy-based resin. The metal support 10 is a member that enhances bending strength when the flexible display device 70 is folded. The configuration of the metal support 10 will be described later.

The heat dissipation layer 77 is a layer that releases heat from the display member 71 to the outside. The heat dissipation layer 77 may be a layer made of metal such as copper or nickel. The heat dissipation layer 77 may be a plated layer produced through electrolytic plating. The casing 78 houses and protects the display member 71, the cushioning layer 76, the metal support 10, and the heat dissipation layer 77. The casing 78 has a structure of being foldable at its center along the folding center line FL.

The flexible display device 70 includes a bending area BA and non-bending areas NA. The bending area BA is an area of physical deformation when the flexible display device 70 is in a folded state (see FIG. 4). The folding center line FL is located at substantially the center of the bending area BA. The non-bending area NA is an area that is substantially free from deformation when the flexible display device 70 is in a folded state (see FIG. 4). In the first direction D1, the non-bending areas NA exist respectively on both sides with respect to the bending area BA. The two non-bending areas NA may have substantially the same length in the first direction D1. This does not imply any limitation. The two non-bending areas NA may have lengths different from each other in the first direction D1. The bending area BA exists at the center of the flexible display device 70 in the first direction D1. This does not imply any limitation. The bending area BA may be located at any position other than the center of the flexible display device 70 in the first direction D1.

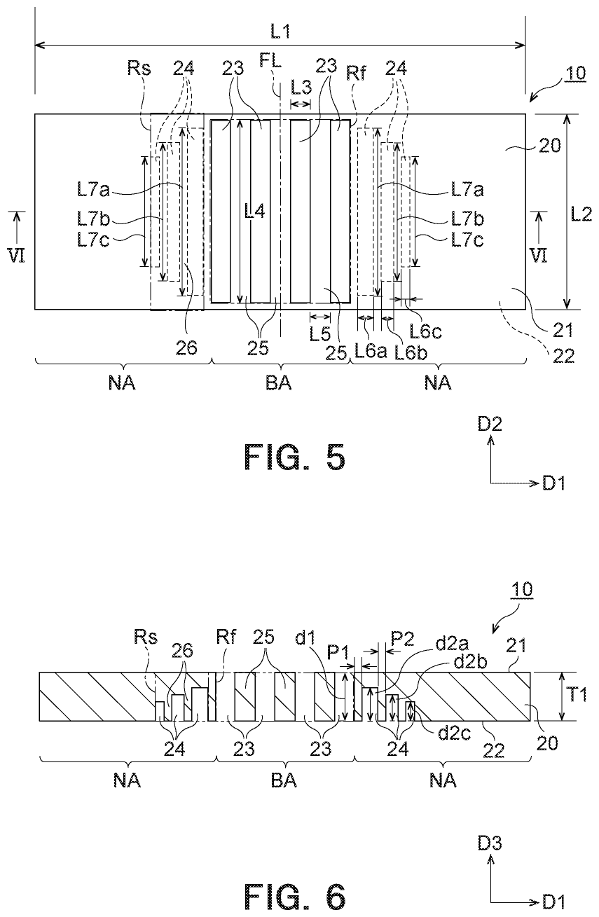

Configuration of Flexible Display Device Metal Support With reference to FIGS. 5 and 6, an overview of a flexible display device metal support according to the present embodiment is presented below. FIGS. 5 and 6 are diagrams illustrating a flexible display device metal support according to the present embodiment.

As illustrated in FIGS. 5 and 6, the metal support 10 includes a base material 20. The base material 20 includes a first surface 21, a second surface 22, a first hole(s) 23, and a second hole(s) 24. The first surface 21 is a surface facing toward the display member 71 of the flexible display device 70. The second surface 22 is a surface facing toward the heat dissipation layer 77 of the flexible display device 70. The second surface 22 is located on the side that is the opposite of the first surface 21. Each of the first surface 21 and the second surface 22 is parallel to a plane formed by an axis of the first direction D1 and an axis of the second direction D2. The first hole 23 is formed in at least the second surface 22. The second hole 24 is formed in the second surface 22 but may be formed in the first surface 21. The second hole 24 is located adjacent to the first hole 23 in the first direction D1.

The metal support 10 includes a bending area BA and non-bending areas NA. The bending area BA is an area of physical deformation when the flexible display device 70 is in a folded state (see FIG. 4). The folding center line FL is located at substantially the center of the bending area BA. The non-bending area NA is an area that is substantially free from deformation when the flexible display device 70 is in a folded state (see FIG. 4). The bending area BA and the non-bending area NA correspond respectively to the bending area BA and the non-bending area NA of the flexible display device 70 described above.

The base material 20 is a member that enhances bending strength when the flexible display device 70 is folded. The base material 20 has a rectangular shape in a plan view. A pair of the longer sides of this rectangle is parallel to the first direction D1, and a pair of the shorter sides of this rectangle is parallel to the second direction D2. Note that this does not imply any limitation. A pair of the shorter sides may be parallel to the first direction D1, and a pair of the longer sides may be parallel to the second direction D2. Each corner portion of this rectangle may be rounded. The base material 20 may have a square shape, a polygonal shape, or a circular shape in a plan view. The planar shape of the base material 20 may correspond to the planar shape of the flexible display device 70. In this case, the planar shape of the base material 20 may be the same as the planar shape of the flexible display device 70. Alternatively, the planar shape of the base material 20 may be smaller than the planar shape of the flexible display device 70.

The base material 20 has a flexible, bendable, and thin shape. In this specification, the term “flexible” means “the ability to be bent to a radius of curvature of at most 5.0 mm or less, or more preferably, 3.0 mm or less.

The length L1 of the base material 20 in the first direction D1 may be 100 mm or greater, or may be 200 mm or greater. The length L1 of the base material 20 in the first direction D1 may be 500 mm or less, or may be 400 mm or less. The length L2 of the base material 20 in the second direction D2 may be 50 mm or greater, or may be 150 mm or greater. The length L2 of the base material 20 in the second direction D2 may be 400 mm or less, or may be 350 mm or less.

The thickness T1 of the base material 20 may be 50 μm or greater, or may be 75 μm or greater. By designing the thickness T1 of the base material 20 to be 50 μm or greater, it is possible to suppress the base material 20 failing to fulfill its function as a support due to an insufficient strength. The thickness T1 of the base material 20 may be 150 μm or less. By designing the thickness T1 of the base material 20 to be 150 μm or less, it is possible to make the radius of curvature of the bending area BA small and improve bending resistance. Moreover, it is possible to suppress excessive heaviness of the metal support 10.

The base material 20 is made of metal. The base material 20 contains a principal metal material. An iron alloy such as stainless steel, titanium, an aluminum alloy, or a magnesium alloy may be used as the principal metal material of the base material 20. In a case where stainless steel is used as the principal metal material of the base material 20, it is easier to bend the base material 20 because the base material 20 has good spring property. In this specification, the term “principal metal material” means a metal material whose content in a certain member is in excess of 50 percent by mass, or more preferably, in excess of 80 percent by mass.

The base material 20 includes the plurality of first holes 23. The plurality of first holes 23 is provided in the bending area BA. The plurality of first holes 23 may be formed in a pattern of lines. The plurality of first holes 23 may be arranged in parallel with one another. The plurality of first holes 23 may have the same planar shape or planar shapes different from one another. The plurality of first holes 23 may have the same depth or depths different from one another. Each of the first holes 23 extends linearly in the second direction D2. Each of the first holes 23 may have a rectangular shape in a plan view. This does not imply any limitation. Each of the first holes 23 may have, for example, a polygonal shape or a circular shape in a plan view. Each of the first holes 23 may have a rectangular shape with rounded corners in a plan view. Each of the first holes 23 may exist at only a part of the base material 20 in the second direction D2.

Each of the first holes 23 is open in both of the first surface 21 and the second surface 22. That is, each of the first holes 23 is a through hole going through the base material 20 in the thickness direction. Since the first holes 23 are through holes, it is possible to further reduce the radius of curvature of the bending area BA when the metal support 10 is folded. Moreover, it is possible to make the weight of the metal support 10 lighter. In this specification, a “hole” is a concept that encompasses both a non-through hole and a through hole.

The length L3 of each of the first holes 23 in the first direction D1 may be 50 μm or greater, or may be 100 μm or greater. The length L3 of each of the first holes 23 in the first direction D1 may be 1000 μm or less, or may be 500 μm or less. The length L4 of each of the first holes 23 in the second direction D2 may be 50 mm or greater, or may be 100 mm or greater. The length L4 of each of the first holes 23 in the second direction D2 may be 400 mm or less, or may be 300 mm or less. The length L4 of each of the first holes 23 in the second direction D2 may be the same as the length L2 of the base material 20 in the second direction D2. Each of the length L3 and the length L4 refers to a distance on the second surface 22. The depth d1 of the first hole 23, which is a through hole, is equal to the thickness T1 of the base material 20.

The base material 20 includes a plurality of first banks 25 in the bending area BA. Each of the first banks 25 extends linearly in the second direction D2. The plurality of first banks 25 is arranged with spacing from one another in the first direction D1. The first hole 23 is formed each between the plurality of first banks 25. That is, the first holes 23 and the first banks 25 are formed alternately in the first direction D1. In this case, since the first holes 23 and the first banks 25 are arranged alternately, it is possible to mitigate stress concentration at a particular portion in the bending area BA when the flexible display device 70 is folded.

The plurality of first banks 25 is arranged in parallel with one another. The plurality of first banks 25 may have the same shape or shapes different from one another. Each of the first banks 25 may have a rectangular shape in a plan view. This does not imply any limitation. Each of the first banks 25 may have a shape that surrounds the first hole 23 in a plan view. Each of the first banks 25 may extend throughout the entirety of the base material 20 in the second direction D2, or may exist at only a part of the base material 20 in the second direction D2. Each of the first banks 25 is thinned neither from the side where the first surface 21 is located nor from the side where the second surface 22 is located. The thickness of each of the first banks 25 is the same as the thickness T1 of the base material 20.

The length L5 of each of the first banks 25 in the first direction D1 may be 50 μm or greater, or may be 100 μm or greater. The length L5 of each of the first banks 25 in the first direction D1 may be 400 μm or less, or may be 200 μm or less. The length L5 refers to a distance on the second surface 22. The length of each of the first banks 25 in the second direction D2 may be the same as the length L2 of the base material 20 in the second direction D2.

The length L5 of each of the first banks 25 in the first direction D1 may be the same as that of the others thereof. Alternatively, the length L5 of each of the first banks 25 in the first direction D1 may vary depending on the location of the first bank 25. For example, the length L5, in the first direction D1, of the first bank 25 located near the folding center line FL may be designed to be greater than the length L5, in the first direction D1, of the first bank 25 located away from the folding center line FL. This makes it possible to suppress the application of a load at, of the bending area BA, a portion that is close to the folding center line FL and is thus prone to having a small radius of curvature when the metal support 10 is folded.

The plurality of second holes 24 is located at, of each of the non-bending areas NA, a regional portion that adjoins the bending area BA. The plurality of second holes 24 may be formed in a pattern of lines. The plurality of second holes 24 is arranged with spacing from one another in the first direction D1. The plurality of second holes 24 may be arranged in parallel with one another. The planar shapes of the plurality of second holes 24 are different from one another; however, they may have the same planar shape. The depths of the plurality of second holes 24 are different from one another; however, they may have the same depth. Each of the second holes 24 extends linearly in the second direction D2. Each of the second holes 24 may have a rectangular shape in a plan view. This does not imply any limitation. Each of the second holes 24 may have, for example, a polygonal shape or a circular shape in a plan view. Each of the second holes 24 may have a rectangular shape with rounded corners in a plan view. Each of the second holes 24 extends at only a part of the base material 20 in the second direction D2; instead, each of them may exist throughout the entirety of the base material 20 in the second direction D2. There exist three second holes 24 in each of the non-bending areas NA; however, the number of the second holes existing in each of the non-bending areas NA may be one or greater and 200 or less.

Each of the second holes 24 is formed by thinning the base material 20 from the side where the second surface 22 is located. Each of the second holes 24 does not reach the first surface 21. That is, each of the second holes 24 is a non-through hole, which does not go through the base material 20 in the thickness direction. Each of the second holes 24 may be a hole formed by means of half etching. Each of the second holes 24 may be formed by thinning the base material 20 from the side where the first surface 21 is located. In this specification, the term “half etching” means etching halfway through an etching target material in its thickness direction. The thickness of the etching target material after the half etching is, for example, 30% or greater and 90% or less of the thickness of the etching target material before the half etching, or more preferably, 40% or greater and 80% or less thereof.

At least one of the second holes 24 is located adjacent to at least one of the first holes 23 in the first direction D1. Specifically, the second hole 24 that is the one located closest to the bending area BA among the second holes 24 located in the non-bending area NA is located adjacent to the first hole 23 that is the one located closest to the non-bending area NA among the first holes 23 located in the bending area BA. In this specification, the meaning of “the second hole 24 is located adjacent to the first hole 23” is that no other hole exists between this second hole 24 and this first hole 23. The pitch P1 between the second hole 24 and the first hole 23 that are located adjacent to each other may be 20 μm or greater and 500 μm or less.

With regard to at least the second hole 24 and the first hole 23 that are located adjacent to each other, the length L6a of the second hole 24 in the first direction D1 is less than the length L3 of the first hole 23 in the first direction D1. This makes it possible to suppress stress concentration at the boundary between the bending area BA and the non-bending area NA as will be described later. Moreover, this makes it possible to suppress the occurrence of deformation such as the forming of a crease at the boundary between the bending area BA and the non-bending area NA. All of the lengths L6a, L6b, and L6c of the plurality of second holes 24 in the first direction D1 may be less than the length L3 of the first hole 23 in the first direction D1.

The plurality of second holes 24 may be arranged such that, the farther from the first hole 23, the less the lengths L6a, L6b, and L6c of them in the first direction D1 are. Specifically, the length L6b, in the first direction D1, of the second hole 24 that is the second closest to the first hole 23 is less than the length L6a, in the first direction D1, of the second hole 24 that is the closest to the first hole 23. Similarly, the length in the first direction D1 of the second hole 24 that is the N+1th closest to the first hole 23 is less than the length in the first direction D1 of the second hole 24 that is the Nth closest to the first hole 23 (where N is a natural number). Each of the lengths L6a, L6b, and L6c of the second holes 24 in the first direction D1 may be 5 μm or greater, or may be 50 μm or greater. Each of the lengths L6a, L6b, and L6c of the second holes 24 in the first direction D1 may be 400 μm or less, or may be 100 μm or less. Each of the lengths L6a, L6b, and L6c refers to a distance on the surface at which the second hole 24 is open, that is, in this case, the distance on the second surface 22.

With regard to at least the second hole 24 and the first hole 23 that are located adjacent to each other, the length L7a of the second hole 24 in the second direction D2 is less than the length L4 of the first hole 23 in the second direction D2. This makes it possible to suppress stress concentration at the boundary between the bending area BA and the non-bending area NA as will be described later. Moreover, this makes it possible to suppress the occurrence of deformation such as the forming of a crease at the boundary between the bending area BA and the non-bending area NA. All of the lengths L7a, L7b, and L7c of the plurality of second holes 24 in the second direction D2 may be less than the length L4 of the first hole 23 in the second direction D2.

The plurality of second holes 24 may be arranged such that, the farther from the first hole 23, the less the lengths L7a, L7b, and L7c of them in the second direction D2 are. Specifically, the length L7b, in the second direction D2, of the second hole 24 that is the second closest to the first hole 23 is less than the length L7a, in the second direction D2, of the second hole 24 that is the closest to the first hole 23. Similarly, the length in the second direction D2 of the second hole 24 that is the N+1th closest to the first hole 23 is less than the length in the second direction D2 of the second hole 24 that is the Nth closest to the first hole 23 (where N is a natural number). Each of the lengths L7a, L7b, and L7c of the second holes 24 in the second direction D2 may be 50 μm or greater, or may be 200 μm or greater. Each of the lengths L7a, L7b, and L7c of the second holes 24 in the second direction D2 may be 95% or less of the length L2 of the base material 20 in the second direction D2, or may be 80% or less thereof. Each of the lengths L7a, L7b, and L7c of the second holes 24 in the second direction D2 may be the same as the length L2 of the base material 20 in the second direction D2. Each of the lengths L7a, L7b, and L7c refers to a distance on the surface at which the second hole 24 is open, that is, in this case, the distance on the second surface 22.

With regard to at least the second hole 24 and the first hole 23 that are located adjacent to each other, the depth d2a of the second hole 24 is less than the depth d1 of the first hole 23. This makes it possible to suppress stress concentration at the boundary between the bending area BA and the non-bending area NA as will be described later. Moreover, this makes it possible to suppress the occurrence of deformation such as the forming of a crease at the boundary between the bending area BA and the non-bending area NA. All of the depths d2a, d2b, and d2c of the plurality of second holes 24 may be less than the depth d1 of the first hole 23.

The plurality of second holes 24 may be arranged such that, the farther from the first hole 23, the less the depths d2a, d2b, and d2c of them are. Specifically, the depth d2b of the second hole 24 that is the second closest to the first hole 23 is less than the depth d2a of the second hole 24 that is the closest to the first hole 23. Similarly, the depth of the second hole 24 that is the N+1th closest to the first hole 23 is less than the depth of the second hole 24 that is the Nth closest to the first hole 23 (where N is a natural number). Each of the depths d2a, d2b, and d2c of the second holes 24 may be 10% or greater of the thickness T1 of the base material 20, or may be 50% or greater thereof. Each of the depths d2a, d2b, and d2c of the second holes 24 may be 100% or less of the thickness T1 of the base material 20, or may be 80% or less thereof.

The pitch P2 of the plurality of second holes 24 may be less than the length L5 of the first bank 25 in the first direction D1, may be the same as the length L5 thereof, or may be greater than the length L5 thereof. The pitch P2 of the plurality of second holes 24 may be uniform. The plurality of second holes 24 may be arranged such that, the farther from the first hole 23, the greater the pitch P2 of them is, or the less the pitch P2 of them is. The pitch P2 of the plurality of second holes 24 each may be 50 μm or greater, or may be 100 μm or greater. The pitch P2 of the plurality of second holes 24 each may be 400 μm or less, or may be 200 μm or less. The pitch P2 of the second holes 24 each refers to a distance on the surface at which the second holes 24 are open, that is, in this case, the distance on the second surface 22.

Each of second banks 26 extends linearly in the second direction D2. The plurality of second banks 26 is arranged with spacing from one another in the first direction D1. The second hole 24 is formed each between the plurality of second banks 26. That is, the second holes 24 and the second banks 26 are formed alternately in the first direction D1. The plurality of second banks 26 is arranged in parallel with one another. The plurality of second banks 26 may have the same shape or shapes different from one another. Each of the second banks 26 may have a rectangular shape in a plan view. This does not imply any limitation. Each of the second banks 26 may have a shape that surrounds the second hole 24 in a plan view. Each of the second banks 26 may extend throughout the entirety of the base material 20 in the second direction D2, or may exist at only a part of the base material 20 in the second direction D2. Each of the second banks 26 is thinned neither from the side where the first surface 21 is located nor from the side where the second surface 22 is located. The thickness of each of the second banks 26 is the same as the thickness T1 of the base material 20.

The plurality of first holes 23 is formed in a first region Rf of the base material 20. The first region Rf may be the same as the bending area BA, or may be narrower than the bending area BA. The first region Rf is a rectangular parallelepiped, and has a rectangular shape in a plan view. This rectangle is a minimum rectangle that extends throughout the entirety of the base material 20 in the second direction D2 and includes all of the first holes 23 in a plan view. The first region Rf refers to an area in a plan view.

The plurality of second holes 24 is formed in a second region(s) Rs of the base material 20. The second region Rs may be a part of each of the non-bending areas NA. The second region Rs may be called “buffering area”. The second region Rs is a rectangular parallelepiped, and has a rectangular shape in a plan view. This rectangle is a minimum rectangle that extends throughout the entirety of the base material 20 in the second direction D2 and includes all of the second holes 24 in a plan view. The second region Rs refers to an area in a plan view.

The percentage of the volume of the first holes 23 to the volume of the entirety in the thickness direction of the metal support 10 at the first region Rf is greater than the percentage of the volume of the second holes 24 to the volume of the entirety in the thickness direction of the metal support 10 at the second region Rs. The volume of the entirety in the thickness direction of the metal support 10 at the first region Rf means the volume of a rectangular parallelepiped the planar shape of which is a rectangle constituting the first region Rf and the thickness of which is the entire thickness of the metal support 10. The volume of the first holes 23 means the sum of the volumes of all of the first holes 23 between the first surface 21 and the second surface 22. The volume of the entirety in the thickness direction of the metal support 10 at the second region Rs means the volume of a rectangular parallelepiped the planar shape of which is a rectangle constituting the second region Rs and the thickness of which is the entire thickness of the metal support 10. The volume of the second holes 24 means the sum of the volumes of all of the second holes 24 between the first surface 21 and the second surface 22.

The percentage of the volume of the first holes 23 to the volume of the entirety in the thickness direction of the metal support 10 at the first region Rf may be 50% or greater, or may be 70% or greater. The percentage of the volume of the first holes 23 to the volume of the entirety in the thickness direction of the metal support 10 at the first region Rf may be 90% or less, or may be 80% or less. The percentage of the volume of the second holes 24 to the volume of the entirety in the thickness direction of the metal support 10 at the second region Rs may be 10% or greater, or may be 20% or greater. The percentage of the volume of the second holes 24 to the volume of the entirety in the thickness direction of the metal support 10 at the second region Rs may be 50% or less, or may be 40% or less.

By designing the percentage of the volume of the first holes 23 to the volume of the entirety in the thickness direction of the metal support 10 at the first region Rf to be greater than the percentage of the volume of the second holes 24 to the volume of the entirety in the thickness direction of the metal support 10 at the second region Rs, it is possible to suppress stress concentration at the boundary between the bending area BA and the non-bending area NA. Moreover, it is possible to suppress the occurrence of deformation such as the forming of a crease at the boundary between the bending area BA and the non-bending area NA.

Though a case where the first holes 23 are through holes has been taken as an example in describing the present embodiment, this does not imply any limitation. Each of the first holes 23 may be a non-through hole that is formed by thinning the base material 20 from the side where the second surface 22 is located and does not go through the base material 20 in the thickness direction. Each of the first holes 23 may be a hole formed by means of half etching. The depth d1 of each of the first holes 23 may be 30% or greater of the thickness T1 of the base material 20, or may be 40% or greater thereof. The depth d1 of each of the first holes 23 may be 90% or less of the thickness T1 of the base material 20, or may be 80% or less thereof. In this case, the depth of each of the second holes 24 may be less than the depth d1 of the first hole 23. The plurality of second holes 24 may be arranged such that, the farther from the first hole 23, the shallower in depth they are. The length L6 of the second hole 24 in the first direction D1 may be less than the length L3 of the first hole 23 in the first direction D1, or may be the same as the length L3 of the first hole 23 in the first direction D1. The length of the second hole 24 in the second direction D2 may be the same as the length of the first hole 23 in the second direction D2, or may be less than the length of the first hole 23 in the second direction D2. Each of the first holes 23 may extend throughout the entirety of the base material 20 in the second direction D2, or may exist at only a part of the base material 20 in the second direction D2. In a case where each of the first holes 23 is designed to be a non-through hole, neither the first holes 23 nor the second holes 24 are open at the first surface 21, which faces toward the display member 71 of the flexible display device 70. In this case, it is possible to suppress the influence on the display member 71 that would otherwise be caused by irregularities arising from the first holes 23 and the second holes 24. This makes it possible to enhance the flatness of the flexible display device 70.

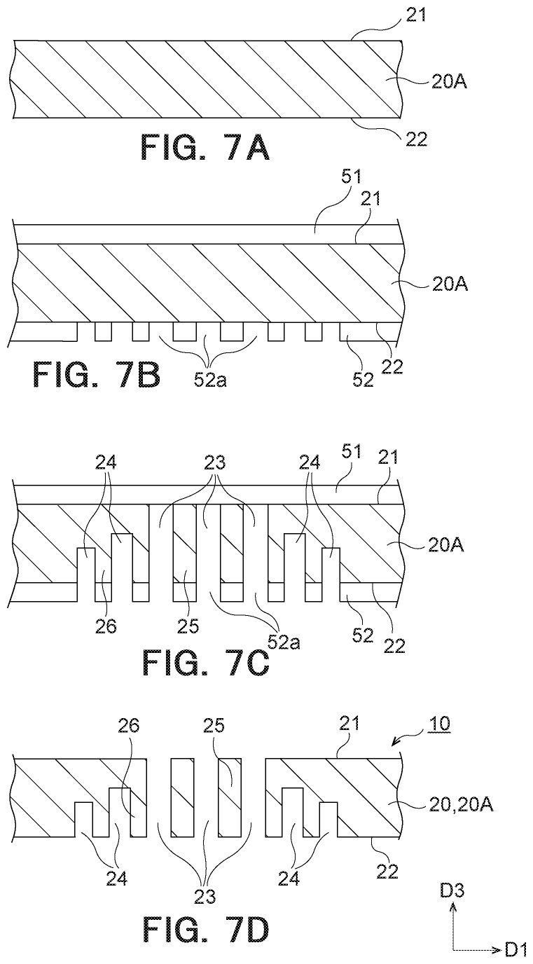

Method of Manufacturing Flexible Display Device Metal Support Next, with reference to FIGS. 7A to 7D, a method of manufacturing the metal support 10 illustrated in FIGS. 5 and 6 will now be described.

First, as illustrated in FIG. 7A, a flat-plate-like base material 20A having not been etched is prepared. An iron alloy such as stainless steel, or titanium, may be used as the base material 20A. The base material 20A has a first surface 21 and a second surface 22. A substrate the first surface 21 and the second surface 22 of which has been cleaned by performing degreasing or the like thereon may be used as the base material 20A.

Next, as illustrated in FIG. 7B, a first protection layer 51 and a second protection layer 52 are provided on the base material 20A. Specifically, the first protection layer 51 is provided on the first surface 21 of the base material 20A, and the second protection layer 52 having second protection layer openings 52a is provided on the second surface 22 of the base material 20A. The first protection layer 51 may be opening-less. Each of the first protection layer 51 and the second protection layer 52 may be a resist layer. In this case, first, a photosensitive resist is applied to the entirety of each of the first surface 21 and the second surface 22 of the base material 20A, and the photosensitive resist is dried. After the resist application and the resist drying, the photosensitive resist on each of the first surface 21 and the second surface 22 of the base material 20A is exposed to light, with a photomask interposed therebetween, for development. Through this process, the first protection layer 51 is formed on the first surface 21 of the base material 20A, and the second protection layer 52 having the second protection layer openings 52a is formed on the second surface 22 thereof. The planar shape of the second protection layer openings 52a corresponds to the planar shape of the first holes 23 and the second holes 24.

Next, as illustrated in FIG. 7C, etching is applied to the second surface 22 of the base material 20A by using an etchant while using the second protection layer 52 as an etching-resistant film. The etchant can be selected as appropriate, depending on the material of which the base material 20A is made. For example, in a case where stainless steel is used as the base material 20A, a mixed liquid that contains ferric chloride as a chief constituent with hydrochloric acid, or a mixed liquid that further contains nitric acid in addition thereto, may be used as the etchant. The etchant described above may be spray-etched onto the base material 20A. Through this process, the base material 20A is etched from the side where the second surface 22 is located, and the first holes 23 going through the base material 20A and the second holes 24 not going through the base material 20A are formed. As described above, the length of the second hole 24 in the first direction D1 is less than the length of the first hole 23 in the first direction D1. The length of the second hole 24 in the second direction D2 is less than the length of the first hole 23 in the second direction D2. The depth of the second hole 24 is less than the depth of the first hole 23.

After that, as illustrated in FIG. 7D, each of the first protection layer 51 on the first surface 21 of the base material 20A and the second protection layer 52 on the second surface 22 of the base material 20A is removed. In this way, the metal support 10 illustrated in FIGS. 5 and 6 are obtained.

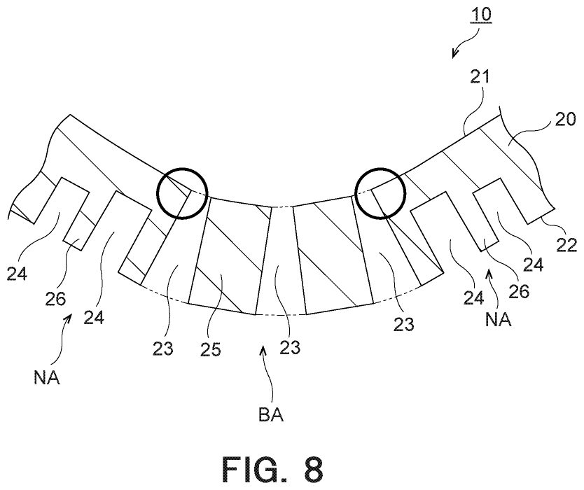

As described above, according to the present embodiment, the base material 20 includes the first holes 23. Therefore, when the metal support 10 is built into the flexible display device 70, it is possible to enhance the bendability of the bending area BA of the flexible display device 70. Consequently, as illustrated in FIG. 8, when the flexible display device 70 is folded, it is possible to further reduce the radius of curvature of the bending area BA.

In the flexible display device 70, the bending area BA undergoes folding repeatedly. The boundary portion (encircled in FIG. 8) between the bending area BA and the non-bending area NA is prone to stress concentration when folded. For this reason, there is a risk that the folding at the bending area BA repeatedly might deteriorate the boundary portion between the bending area BA and the non-bending area NA, resulting in the breakage of the boundary portion. Moreover, the strength of the metal support 10 changes significantly at the boundary portion between the bending area BA and the non-bending area NA. For this reason, there is a risk that the folding at the bending area BA repeatedly might distort the bending area BA and the non-bending area NA, with the boundary portion interposed therebetween, resulting in the forming of a crease in the metal support 10.

To address these issues, according to the present embodiment, the second hole(s) 24 is located adjacent to the first hole(s) 23. The second hole(s) 24 is located at the non-bending area(s) NA, and the first hole(s) 23 is located at the bending area BA. The length of the second hole 24 in the first direction D1 is less than the length of the first hole 23 in the first direction D1. The length of the second hole 24 in the second direction D2 is less than the length of the first hole 23 in the second direction D2. The depth of the second hole 24 is less than the depth of the first hole 23. With this structure, it is possible to disperse the stress acting at the boundary portion between the bending area BA and the non-bending area NA to a wide range when the flexible display device 70 is folded repeatedly. In other words, the second hole 24 and an area located around it function as a buffering area, and mitigates the stress acting at the boundary portion between the bending area BA and the non-bending area NA. Consequently, it is possible to suppress the deterioration of the boundary portion when folding is performed at the bending area BA repeatedly and thus to suppress the breakage of the boundary portion. Moreover, it is possible to mitigate the distortion of the bending area BA and the non-bending area NA when folding is performed at the bending area BA repeatedly and thus to suppress the forming of a crease in the metal support 10.

According to the present embodiment, the plurality of second holes 24 is arranged such that, the farther from the first hole 23, the shorter in length in the first direction D1 they are. In addition, the plurality of second holes 24 is arranged such that, the farther from the first hole 23, the shorter in length in the second direction D2 they are. In addition, the plurality of second holes 24 is arranged such that, the farther from the first hole 23, the shallower in depth they are. This makes it possible to more effectively mitigate stress concentration at the boundary portion between the bending area BA and the non-bending area NA. Consequently, it is possible to more effectively suppress the breakage of the boundary portion and more effectively suppress the occurrence of distortion and the forming of a crease in the metal support 10.

According to the present embodiment, the second hole(s) 24 is formed in the second surface 22. The second hole 24 may be absent in the first surface 21 facing toward the display member 71 of the flexible display device 70. In this case, it is possible to suppress the influence of irregularities arising from the second holes 24 on the display member 71. This makes it possible to enhance the flatness of the flexible display device 70.

According to the present embodiment, the first hole(s) 23 is formed in the first region Rf, and the second hole(s) 24 is formed in the second region Rs. The percentage of the volume of the first holes 23 to the volume of the entirety in the thickness direction of the metal support 10 at the first region Rf is greater than the percentage of the volume of the second holes 24 to the volume of the entirety in the thickness direction of the metal support 10 at the second region Rs. This makes it possible to mitigate stress concentration at the boundary portion between the bending area BA and the non-bending area NA. Consequently, it is possible to suppress the breakage of the boundary portion and suppress the occurrence of distortion and the forming of a crease in the metal support 10.

Moreover, according to the present embodiment, since the base material 20 includes the first holes 23 and the second holes 24, it is possible to reduce the weight of the metal support 10.

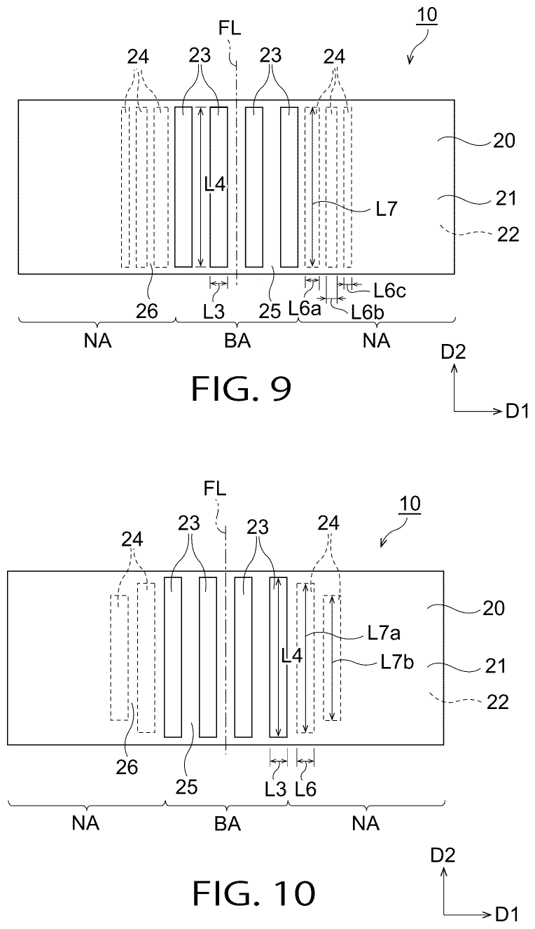

Variation Examples Next, with reference to FIGS. 9 to 14, some various variation examples of the present embodiment will now be described. Each of FIGS. 9 to 14 is a diagram illustrating a variation example of the present embodiment. In FIGS. 9 to 14, the same reference signs are assigned to the same portions as those illustrated in FIGS. 1 to 8, and a detailed explanation thereof will be omitted.

First Variation Example FIG. 9 is a plan view illustrating the metal support 10 according to a first variation example. As illustrated in FIG. 9, in the metal support 10 according to the present variation example, each of the lengths L6a, L6b, and L6c of the plurality of second holes 24 in the first direction D1 is less than the length L3 of the first hole 23 in the first direction D1. In addition, the plurality of second holes 24 is arranged such that, the farther from the first hole 23, the less the lengths L6a, L6b, and L6c of them in the first direction D1 are. The length L7 of the second hole 24 in the second direction D2 is the same as the length L4 of the first hole 23 in the second direction D2; however, the length L7 may be different from the length L4. Each of the second holes 24 extends at only a part of the base material 20 in the second direction D2; instead, each of them may extend throughout the entirety of the base material 20 in the second direction D2. The depth of the second hole 24 may be the same as the depth of the first hole 23, or may be less than the depth of the first hole 23. According to the present variation example, it is possible to suppress stress concentration at the boundary between the bending area BA and the non-bending area NA. Moreover, it is possible to suppress the occurrence of deformation such as the forming of a crease at the boundary between the bending area BA and the non-bending area NA.

Second Variation Example FIG. 10 is a plan view illustrating the metal support 10 according to a second variation example. As illustrated in FIG. 10, in the metal support 10 according to the present variation example, each of the lengths L7a and L7b of the plurality of second holes 24 in the second direction D2 is less than the length L4 of the first hole 23 in the second direction D2. In addition, the plurality of second holes 24 is arranged such that, the farther from the first hole 23, the less the lengths L7a and L7b of them in the second direction D2 are. In this case, the length L6 of the second hole 24 in the first direction D1 is the same as the length L3 of the first hole 23 in the first direction D1. The depth of the second hole 24 may be the same as the depth of the first hole 23, or may be less than the depth of the first hole 23. According to the present variation example, it is possible to suppress stress concentration at the boundary between the bending area BA and the non-bending area NA. Moreover, it is possible to suppress the occurrence of deformation such as the forming of a crease at the boundary between the bending area BA and the non-bending area NA.

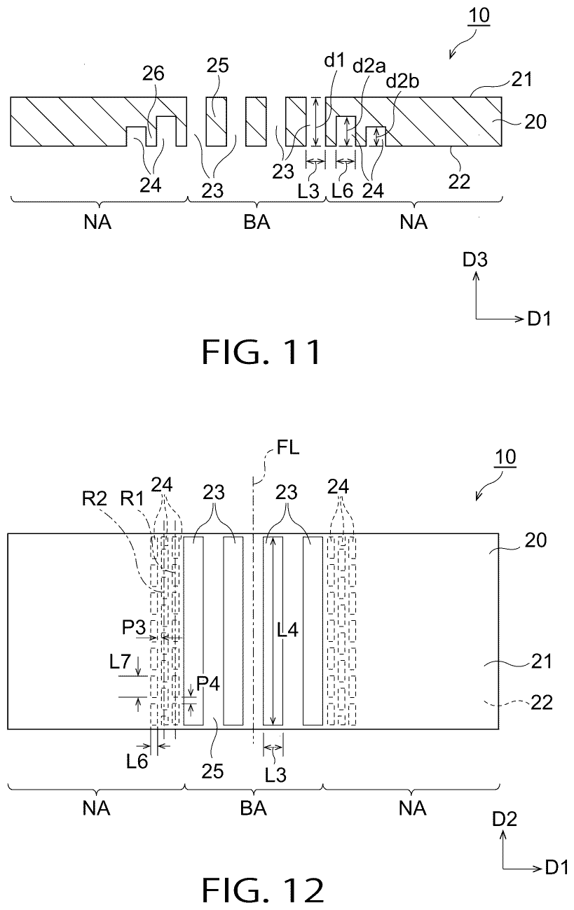

Third Variation Example FIG. 11 is a partial cross-sectional view illustrating the metal support 10 according to a third variation example. As illustrated in FIG. 11, in the metal support 10 according to the present variation example, each of the depths d2a and d2b of the plurality of second holes 24 is less than the depth d1 of the first hole 23. In addition, the plurality of second holes 24 is arranged such that, the farther from the first hole 23, the less the depths d2a and d2b of them are. In this case, the length L6 of the second hole 24 in the first direction D1 is the same as the length L3 of the first hole 23 in the first direction D1. However, the length L6 of the second hole 24 in the first direction D1 may be less than the length L3 of the first hole 23 in the first direction D1. The length of the second hole 24 in the second direction D2 may be the same as the length of the first hole 23 in the second direction D2, or may be less than, or greater than, the length of the first hole 23 in the second direction D2. According to the present variation example, it is possible to suppress stress concentration at the boundary between the bending area BA and the non-bending area NA. Moreover, it is possible to suppress the occurrence of deformation such as the forming of a crease at the boundary between the bending area BA and the non-bending area NA.

Fourth Variation Example FIG. 12 is a plan view illustrating the metal support 10 according to a fourth variation example. As illustrated in FIG. 12, the plurality of second holes 24 may be arranged in a staggered (zigzag) layout. In this case, the plurality of second holes 24 includes the second holes 24 belonging to a first row R1 and the second holes 24 belonging to a second row R2. The second holes 24 belonging to the first row R1 are arranged with spacing from one another in the second direction D2. The second holes 24 belonging to the second row R2 are arranged with spacing from one another in the second direction D2. The second holes 24 belonging to the first row R1 and the second holes 24 belonging to the second row R2 are shifted in position from each other in the second direction D2. The length L6 of each of the second holes 24 in the first direction D1 is less than the length L3 of the first hole 23 in the first direction D1. However, the length L6 of each of the second holes 24 in the first direction D1 may be the same as the length L3 of the first hole 23 in the first direction D1. The length L7 of each of the second holes 24 in the second direction D2 is less than the length L4 of the first hole 23 in the second direction D2. The depth of each of the second holes 24 may be less than the depth of the first hole 23. According to the present variation example, since the plurality of second holes 24 is arranged in a staggered layout, it is possible to suppress stress concentration at a particular portion around the second hole 24 when the flexible display device 70 is folded.

The interval P3 of the second holes 24 arranged adjacent to each other in the first direction D1 may be 20 μm or greater and 500 μm or less. The interval P4 of the second holes 24 arranged adjacent to each other in the second direction D2 may be 20 μm or greater and 200 μm or less. Each of the second holes 24 has a substantially rectangular shape in a plan view. This does not imply any limitation. Each of the second holes 24 may have, for example, a polygonal shape or a circular shape in a plan view. Each of the second holes 24 may have a rectangular shape with rounded corners in a plan view. The length L6 of each of the second holes 24 in the first direction D1 may be 50 μm or greater and 800 μm or less. The length L7 of each of the second holes 24 in the second direction D2 may be 50 μm or greater and 3000 μm or less.

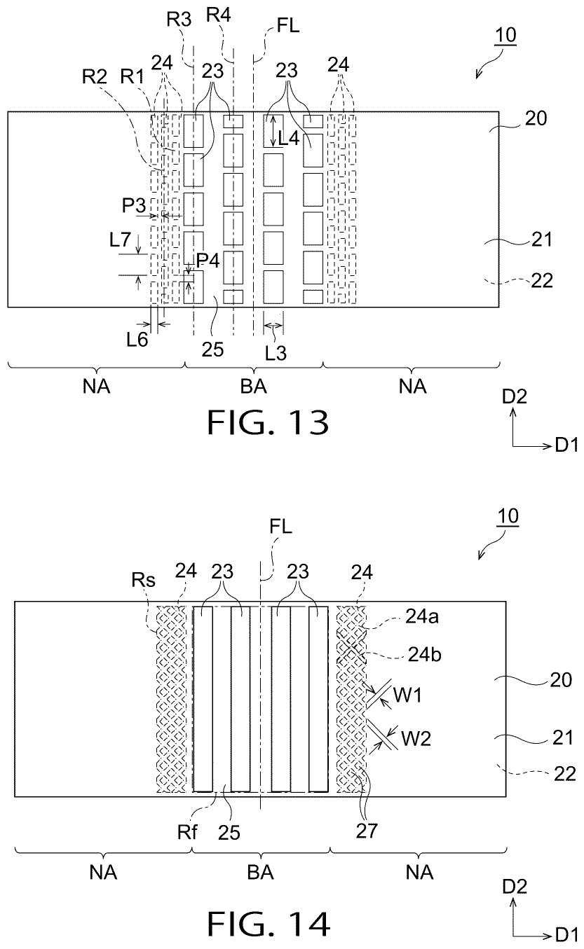

Fifth Variation Example FIG. 13 is a plan view illustrating the metal support 10 according to a fifth variation example. As illustrated in FIG. 13, the plurality of second holes 24 may be arranged in a staggered (zigzag) layout. The plurality of first holes 23 may be arranged in a staggered (zigzag) layout in the bending area BA. In this case, the plurality of first holes 23 includes the first holes 23 belonging to a third row R3 and the first holes 23 belonging to a fourth row R4. The first holes 23 belonging to the third row R3 are arranged with spacing from one another in the second direction D2. The first holes 23 belonging to the fourth row R4 are arranged with spacing from one another in the second direction D2. The first holes 23 belonging to the third row R3 and the first holes 23 belonging to the fourth row R4 are shifted in position from each other in the second direction D2. The length L6 of each of the second holes 24 in the first direction D1 is less than the length L3 of the first hole 23 in the first direction D1. However, the length L6 of each of the second holes 24 in the first direction D1 may be the same as the length L3 of the first hole 23 in the first direction D1. The length L7 of each of the second holes 24 in the second direction D2 is less than the length L4 of the first hole 23 in the second direction D2. However, The length L7 of each of the second holes 24 in the second direction D2 may be the same as the length L4 of the first hole 23 in the second direction D2. The depth of each of the second holes 24 may be less than the depth of the first hole 23, or may be the same as the depth of the first hole 23. According to the present variation example, since the plurality of first holes 23 and the plurality of second holes 23 are each arranged in a staggered layout, it is possible to suppress stress concentration at a particular portion around the first hole 23 and at a particular portion around the second hole 24 when the flexible display device 70 is folded.

Each of the first holes 23 has a substantially rectangular shape in a plan view. This does not imply any limitation. Each of the first holes 23 may have, for example, a polygonal shape or a circular shape in a plan view. Each of the first holes 23 may have a rectangular shape with rounded corners in a plan view. The length L3 of each of the first holes 23 in the first direction D1 may be 50 μm or greater and 1000 μm or less. The length L4 of each of the first holes 23 in the second direction D2 may be 200 μm or greater and 3000 μm or less. In FIG. 13, the configuration of the second holes 24 may be the same as the configuration of the second holes 24 according to the fourth variation example (FIG. 12).

Sixth Variation Example FIG. 14 is a plan view illustrating the metal support 10 according to a sixth variation example. As illustrated in FIG. 14, the second hole 24 may include a plurality of first linear grooves 24a extending linearly and a plurality of second linear grooves 24b extending linearly. The plurality of first linear grooves 24a extend in parallel with one another. The plurality of second linear grooves 24b extend in parallel with one another. Each of the first linear grooves 24a and each of the second linear grooves 24b intersect with each other in a non-parallel manner. Each of the first linear grooves 24a and each of the second linear grooves 24b may be orthogonal to each other. In addition, each of the first linear grooves 24a and each of the second linear grooves 24b extends in a direction different from the first direction D1 and different from the second direction D2. Specifically, each of the first linear grooves 24a intersects with the first direction D1 and the second direction D2, each at an angle of 45°. Specifically, each of the second linear grooves 24b intersects with the first direction D1 and the second direction D2, each at an angle of 45°. At least one of each of the first linear grooves 24a or each of the second linear grooves 24b may extend in parallel with the first direction D1 or the second direction D2. The width W1 of each of the first linear grooves 24a may be 50 μm or greater and 500 μm or less. The width W2 of each of the second linear grooves 24b may be 50μm or greater and 500 μm or less.

A third bank 27 is formed at each area enclosed by two first linear grooves 24a located adjacent to each other and two second linear grooves 24b located adjacent to each other. The third bank 27 may have a rectangular shape or a square shape in a plan view. Each of the third banks 27 is thinned neither from the side where the first surface 21 is located nor from the side where the second surface 22 is located. The thickness of each of the third banks 27 is the same as the thickness of the base material 20.

In FIG. 14, the plurality of first holes 23 is formed in the first region Rf. The second hole 24 is formed in the second region Rs. The percentage of the volume of the plurality of first holes 23 to the volume of the entirety in the thickness direction of the metal support 10 at the first region Rf is greater than the percentage of the volume of the second hole 24 to the volume of the entirety in the thickness direction of the metal support 10 at the second region Rs. The depth of the second hole 24 may be less than the depth of each of the first holes 23. According to the present variation example, the second hole 24 includes the plurality of first linear grooves 24a extending linearly and the plurality of second linear grooves 24b extending linearly, and each of the first linear grooves 24a and each of the second linear grooves 24b intersect with each other in a non-parallel manner. This makes it possible to suppress stress concentration at a particular portion around the second hole 24 when the flexible display device 70 is folded.

The plurality of components disclosed in the foregoing embodiments and the variation examples can be combined together as needed. Alternatively, some of all of the components disclosed in the foregoing embodiments and the variation examples may be deleted.

1. A flexible display device metal support, comprising:
a first surface;
a second surface opposite to the first surface;
a first hole formed in the second surface; and
a second hole formed in the first surface or the second surface, wherein
each of the first surface and the second surface is parallel to a plane formed by an axis of a first direction and an axis of a second direction,
the second hole is located adjacent to the first hole in the first direction, and a length of the second hole in the first direction is less than a length of the first hole in the first direction, or a length of the second hole in the second direction is less than a length of the first hole in the second direction.

2. The flexible display device metal support according to claim 1, wherein a plurality of second holes, each as the second hole, is formed in the first direction, and
the farther from the first hole, the shorter in length in the first direction or in length in the second direction the plurality of second holes is.

3. A flexible display device metal support, comprising:
a first surface;
a second surface opposite to the first surface;
a first hole formed in the second surface; and
a second hole formed in the first surface or the second surface, wherein
each of the first surface and the second surface is parallel to a plane formed by an axis of a first direction and an axis of a second direction,
the second hole is located adjacent to the first hole in the first direction, and a depth of the second hole is less than a depth of the first hole.

4. The flexible display device metal support according to claim 3, wherein a plurality of second holes, each as the second hole, is formed in the first direction, and
the farther from the first hole, the shallower in depth the plurality of second holes is.

5. A flexible display device metal support, comprising:
a first surface;
a second surface opposite to the first surface;
a first hole formed in the second surface; and
a second hole formed in the first surface or the second surface, wherein
each of the first surface and the second surface is parallel to a plane formed by an axis of a first direction and an axis of a second direction,
the second hole is located adjacent to the first hole in the first direction,
the first hole is formed in a first region, the first region being, in a plan view,
a minimum rectangle extending throughout an entirety in the second direction and including all of first holes each as the first hole,
the second hole is formed in a second region, the second region being, in a plan view, a minimum rectangle extending throughout the entirety in the second direction and including all of second holes each as the second hole, and
a percentage of a volume of the first holes to a volume of an entirety in a thickness direction of the flexible display device metal support at the first region is greater than a percentage of a volume of the second holes to a volume of the entirety in the thickness direction of the flexible display device metal support at the second region.

6. The flexible display device metal support according to claim 5, wherein the second hole includes a plurality of first linear grooves extending linearly and a plurality of second linear grooves extending linearly, and
each of the first linear grooves and each of the second linear grooves intersect with each other in a non-parallel manner.

7. The flexible display device metal support according to claim 1, wherein the first hole is a non-through hole.

8. The flexible display device metal support according to claim 1, wherein the first hole is a through hole.

9. The flexible display device metal support according to claim 1, wherein a plurality of second holes, each as the second hole, is formed, and the plurality of second holes is arranged in a staggered manner.

10. A flexible display device, comprising:
a display member; and
the flexible display device metal support according to claim 1 supporting the display member.

11. The flexible display device metal support according to claim 3, wherein the first hole is a non-through hole.

12. The flexible display device metal support according to claim 3, wherein the first hole is a through hole.

13. The flexible display device metal support according to claim 3, wherein a plurality of second holes, each as the second hole, is formed, and the plurality of second holes is arranged in a staggered manner.

14. A flexible display device, comprising:
a display member; and
the flexible display device metal support according to claim 3 supporting the display member.

15. The flexible display device metal support according to claim 5, wherein the first hole is a non-through hole.

16. The flexible display device metal support according to claim 5, wherein the first hole is a through hole.

17. The flexible display device metal support according to claim 5, wherein a plurality of second holes, each as the second hole, is formed, and the plurality of second holes is arranged in a staggered manner.

18. A flexible display device, comprising:
a display member; and
the flexible display device metal support according to claim 5 supporting the display member.
